(19) United States
(12) Patent Application Publication
(10) Pub. No.: US 2014/0024144 A1
(43) Pub. Date: Jan. 23, 2014

(54) INTEGRATED CIRCUIT DIE AND METHOD OF MAKING

(71) Applicant: Texas Instruments Incorporated, Dallas, TX (US)

(72) Inventors: Palkesh Jain, Bangalore (IN); Anand T. Krishnan, Irving, TX (US)

(73) Assignee: TEXAS INSTRUMENTS INCORPORATED, Dallas, TX (US)

(21) Appl. No.: 14/039,055

(22) Filed: Sep. 27, 2013

Related U.S. Application Data
(62) Division of application No. 13/532,558, filed on Jun. 25, 2012.
(60) Provisional application No. 61/502,133, filed on Jun. 28, 2011.

(51) Int. Cl. H01L 21/66

(52) U.S. Cl. CPC H01L 22/10
USPC 438/14

(57) ABSTRACT

Integrated circuit dies and methods of making dies are disclosed. An embodiment of a die includes at least one transistor gate, wherein the gate has an area. A conductor is connected to the gate, and wherein the conductor has an area. The area of the conductor is proportional to the area of the gate raised to a power, wherein the power is a function of the failure rate of the gate.

This application is a Divisional of prior application Ser. No. 13/532,558, filed Jun. 25, 2012, currently pending;

Which claims priority to U.S. Provisional Patent Application 61/502,133 for NOVEL, FUNDAMENTALLY DIFFERENT AND PPASSY DRIVEN ANTENNA (PLASMA CHARGING DAMAGE) CHECKING METHOD of Palkesh Jain filed on Jun. 28, 2011, which is incorporated by reference for all that is disclosed therein.

### BACKGROUND

During fabrication of some integrated circuit dies, the dies are exposed to a plasma environment that exposes the dies to very high charges. These charges are harsh and can damage components on the die. For example, during many etching processes, the dies are put into the plasma environment to remove specific layers on the die. Components on the dies, such as transistors, are susceptible to plasma charging or antenna damage when they are exposed to the plasma environment. Damage sustained to a die and/or the components located thereon while a die is located in a plasma environment is referred to as plasma induced damage (PID).

In the plasma environment, metals connected to the gate oxides (or simply the gates) of transistors act as antennae and build up a charge. More specifically, the gates may be electrically floating during this state of fabrication, so they accumulate charge in the plasma environment. The charge causes a voltage potential to build up across the gate, which in turn causes a tunneling current to flow through the gate during plasma processing. A high level of tunneling current degrades the gate and causes premature failure of the gate and/or the die.

Currently, an antenna ratio is established during the design of a die in order to determine the areas of the gates and the metals connected to the gates in order to keep the voltage potentials to a constant value or below a constant value. It has been assumed that keeping the voltage potentials to a constant value will reduce damage in the gates due to tunneling. The antenna ratio is proportional to the ratio of the metal area to the gate area, wherein the metal area is the area of metal that is electrically connected to the gate. The antenna ratio is set to be less than a specified value for every individual gate in a specific design. The specified value is calculated by stressing a single transistor design with different antenna ratios. It is assumed that all gates in the die abide by this same charge dissipation rules for a specific antenna ratio. By applying the antenna ratio, the voltage build-up across different gates in the design remains the same.

One problem with the present use of the antenna ratio is that the failure rate of the gates is not necessarily based on the voltage potential that the antenna ratio seeks to remain constant. Accordingly, the present use of the antenna ratio does not provide an accurate fault prediction of the gates.

### SUMMARY

Integrated circuit dies and methods of making dies are disclosed. An embodiment of a die includes at least one transistor gate, wherein the gate has an area. A conductor is connected to the gate, wherein the conductor has an area. The area of the conductor is proportional to the area of the gate raised to a power, wherein the power is a function of the failure rate of the gate.

### BRIEF DESCRIPTION OF THE DRAWINGS

FIG. 1 is an isometric view of an embodiment of a portion of a transistor on an integrated circuit in a plasma environment.

FIG. 2 is a schematic diagram of the transistor of claim 1.

FIG. 3 is a flowchart describing a method of manufacturing dies based on new antenna ratio rules.

### DETAILED DESCRIPTION

Integrated circuits and methods of making integrated circuits are disclosed herein. The integrated circuits disclosed herein have transistors that have gate oxides, or simply gates. During fabrication, the gates are electrically connected to metal layers that may electrically float. The metals or conductors connected to the gates are referred to as antennas. Antenna ratios that are proportional to the areas of the metals connected to the gates to the areas of the gates are calculated. The antenna ratios are used to calculate the areas of the gates in order to achieve a substantially constant fail rate of the gates when the transistors are in a plasma environment. The antenna ratios described herein vary depending on the size of the gates. By this design, transistors with smaller gate areas may be designed and fabricated using antenna ratios that are larger than antenna ratios for transistors having larger gate areas.

Conventional integrated circuits use a constant antenna ratio applied to all gates during the fabrication process. One problem with relying on a constant antenna ratio is that it does not have a good relation to the gate failure rate. More specifically, an integrated circuit design based on a constant antenna ratio ensures that every gate in the design undergoes an equal stress voltage due to the antenna or the metals connected to the gates. However, the Poisson defect distribution statistics have been applied to gate failures due to plasma induced damage and show that for a constant voltage stress, the failure rate probability increases as the gate area increases. Accordingly, transistors with larger gate areas have a greater FIT (Failure-in-time) rate when designed to the same antenna ratio rule as transistors with smaller gate areas. Therefore, transistors with smaller gate areas may be designed to much larger antenna ratios (and thereby higher stress voltages) in order to meet the same FIT rate.

The dies disclosed herein are designed based on a system level failure rate rather than a component level failure rate. Conventional die fabrication uses antenna rules that are derived at a component level. The component level rules establish a FIT rate based on the components. However, a die typically has a circuit or a system that has a large number of components. Reliance on the component level FIT rate leads to situations where the FIT budget allotted to plasma charging damage cannot be properly applied. More specifically, the component rules do not account for losses sustained as a result of plasma charging. One of the problems is that the conventional antenna rules do not provide any controls on the final FIT rate due to plasma induced damage.

Integrated circuit dies and methods of designing and fabricating dies using unique variations of antenna ratios are disclosed herein. The dies and methods described herein overcome the above-described problems related to plasma induced defects (PIDs). In addition, the dies and methods disclosed herein ensure that each gate on a die fails with the same probability, unlike conventional dies and methods where different gates have different fail probabilities.

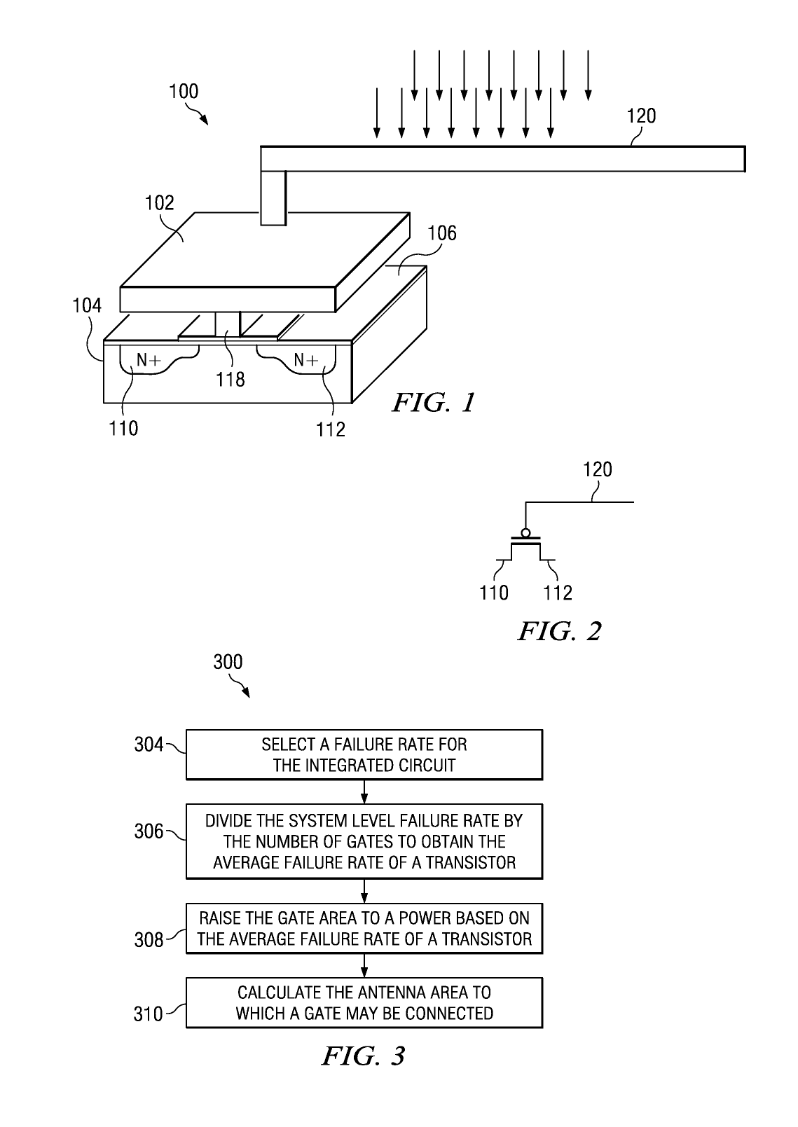

Reference is made to FIG. 1, which is a diagram of a portion of an integrated circuit die 100, referred to simply as the die 100, in a plasma environment. In the embodiment of FIG. 1, the portion of the die 100 that is shown is a single transistor 102. The die 100 has a wafer or substrate 104 with a surface 106 wherein the transistor 102 is being fabricated into or onto the surface 106. It is noted that the die 100 may have many components located thereon, but for illustration purposes, only the single transistor 102 is shown. For example, the die 100 may have millions or billions of transistors that are identical to the transistor 102. The die 100 is in the process of fabrication and is shown in FIG. 1 as being in a plasma environment. The plasma environment may be used in the process of etching the die 100 in a conventional manner.

In the embodiments described herein, the substrate 104 is being fabricated into the transistor 102 and at this point of fabrication, the substrate has two conductors 110, 112 located in or on the surface 106. The conductors 110, 112 may be the drain/source or emitter/collector of the transistor 102. A gate-oxide, or simply a “gate” 118, is located between the conductors 110, 112 and may be the gate or base of the transistor 102. The gate 118 may, as an example, be a polysilicon material.

During this stage of fabrication, the gate 118 is electrically connected to other conductive materials, such as a metal layer 120. The metal layer 120 and other conductive materials electrically connected to the metal layer 120 are referred to collectively as the metal layer 120 or the antenna 120. At this stage in the fabrication of the transistor 102, the gate 118 and the antenna 120 may electrically float, meaning that they are not connected to circuits that can discharge electrical charge that accumulates in the plasma environment. The gate 118 has an area, referred to as the gate area, from where an accumulated charge discharges. For example, the accumulated charge in the gate 118 may discharge to the conductors 110, 112 by way of tunnel currents. The antenna 120 also has an area, referred to as the antenna area, which is the area that the gate 118 sees or that is electrically connected to the gate 118. The antenna 120, by way of its relatively large area, collects charge accumulated in the plasma environment, which is transferred to the gate 118.

For reference, a schematic illustration of the transistor 102 of FIG. 1 is shown in FIG. 2. As shown, the gate 118 is connected to the antenna 120, which is electrically floating. The conductors 110, 112 may or may not be floating, but they are likely to be at a different potential than the gate 118.

When the die 100 is located in the plasma environment, the antenna 120 attracts and accumulates charge generated in the plasma environment. The charge is transferred to the gate 118 where a voltage potential is generated between the gate 118 and other conductors, such as the conductors 110, 112. When the potential is high enough, the gate 118 discharges by way of the tunneling effect to the other conductors. As the charge passes through the gate 118, the charge stresses materials, such as oxides, in the gate 118, which may cause the gate 118 to fail or may cause early failure of the gate 118. The failure of the gate 118 over time is referred to as failure in time (FIT). Failure or defects of the gate 118 as a result of being in the plasma environment are referred to as plasma induced defects (PID).

Having described the process leading to plasma induced defects with the die 100, the die 100 will now be described with the application of antenna ratios that reduce the plasma induced defects. Methods for manufacturing and designing the die 100 will also be described. In summary, the area of the gate 118 and the area of the antenna 120 are described herein such that the probability of plasma induced defects is maintained constant rather than maintaining a constant voltage on the gate 118.

Focusing on the transistor 102 in the plasma environment, the current flow through the antenna 120 is equal to the current through the gate 118. The current flow is equal to the current density (J) multiplied by the area (A) through which the current flows. It follows that:

(Jₐₙₜ)(Aₐₙₜ)=(J_{gate})(A_{gate}) Equation (1)

Jₐₙₜ is the current density of the antenna 120 and other floating conductors electrically connected to the antenna 120. Jₐₙₜ can be assumed to be a constant when the die 100 is in the plasma environment because the charge accumulated by the antenna 120 is constant. Thus, the current density through the gate 118 (J_{gate}) can be expressed as a ratio of antenna area (Aₐₙₜ) to the gate area (A_{gate}), which is also known as the antenna ratio (AR). Equating equation (1) to the tunneling current through the gate 118, the current density through the gate 118 is:

$${J}_{gate} = {J}_{ant} ( AR ) = a {e}^{\frac{qV}{KT}} \qquad Equation ( 2 )$$

Where q is the electron charge, K is the Boltzmann constant, T is temperature, and V is the voltage build-up across the gate 118 that is required to sustain current equal to the current that is due to plasma charging. As shown in equation 2, the current density in the gate is equal to the current density in the antenna multiplied by the antenna ratio. In addition, the current in the gate is limited to the tunneling current, which yields the right side of equation 2. It is noted that the term “a” in equation is a well-known constant associated with tunneling. Equation (2) can be solved for voltage (V), which yields the following equation for voltage:

V=k1·ln(AR) Equation (3)

k1 is a constant that is dependent on the materials used in the die and may be derived from experimentation on the die. Regardless of the constant K1, equation 3 shows that there is a logarithmic relationship between the voltage build up on the gate 118 and the antenna ratio.

The conventional approach towards the problem of plasma induced damage is to design the transistors to keep the voltage, V, constant in the plasma environment. In order to keep the voltage, V, constant in the plasma environment, the antenna ratio must be maintained constant. The approach described herein maintains a constant fail rate rather than a constant voltage on the gate 118. Therefore, the antenna ratio is not necessarily maintained constant for all transistors.

Equation (3) indicates that the damage for a fixed antenna area is less if the collected current passes through a larger gate area because the result is a lower stress current density and stress voltage applied to the gate 118. However, the Poisson defect distribution statistics dictate that, for a fixed stress voltage, as the gate area increases, the failure probability increases due to gate area scaling. Therefore, equation (4) states that the failure rate will decrease with increased gate area and the Poisson defect distribution dictates the opposite for a constant antenna area.

In order to resolve the discrepancy between Equation (3) and the Poisson defect distribution statistics, the average fail rate (AFR) of a transistor due to gate reliability is calculated with respect to the Weibull failure model. The average failure rate of a transistor due to gate reliability loss based on the Weibull failure model is expressed as:

$$AFR = c * {10}^{- α V} * {A}_{gate}^{- 1 / β} \qquad Equation ( 4 )$$

where V is the applied stress voltage, A_{gate} is the area of the gate, and beta is the Weibull slope of the failure model. Alpha is the voltage exponential parameter and c is a constant. The voltage stress of Equation (3) can be substituted into the average fail rate of Equation (4). The result is the fail probability of the gate due to antenna damage, which is expressed as:

$$AFR = C \cdot [ {10}^{- α \cdot K 1 \cdot ln ( AR )} ] \cdot {A}_{GATE}^{- 1 / β} \qquad Equation ( 5 )$$

As described above, the integrated circuits and methods of making integrated circuits described herein are based on a substantially constant fail probability. Therefore, the fail probability needs to be independent of the gate area or the antenna area. By setting the average fail rate to a constant, equation (6) is derived from Equation (5) as follows:

$$ln ( AR ) {A}_{GATE}^{1 / β} = \text{CONSTANT} \qquad Equation ( 6 )$$

By taking the inverse natural log of Equation (6), the antenna ratio is expressed as follows with respect to the constant failure rate, which is denoted as C:

$$\frac{{A}_{ANT}}{{A}_{GATE}} = C \cdot {A}_{GATE}^{- 1 / β} \qquad Equation ( 7 )$$

Therefore, the area of an antenna that will yield a constant fail rate is expressed as Equation (8) as follows:

$${A}_{ANT} = C \cdot {A}_{GATE}^{1 - 1 / β} \qquad Equation ( 8 )$$

Equation 8 includes a value, R, that is related to the Weibull slope of the failure model of the transistor. An empirical value of β may be selected based on the slope. In one embodiment, a value for β is selected as 3.3, so that the equation 1−1/β is equal to approximately 0.7. By using this value in Equation (8), the area of the antenna becomes:

A_{ANT}=k·A_{GATE}^{0.7} Equation (9)

Equation (9) puts a constraint on the antenna area that a gate is connected to in a power law format. Conventional antenna areas are based on linear relationships with the gate area. The conventional antenna areas are also based on a constant stress voltage applied to the gate.

Equation (9) relates to individual transistors. However, the formula can be expanded to an integrated circuit having a plurality of transistors. The average fail rate of an integrated circuit, AFR_{IC}, based on Equation (10) is:

$${AFR}_{IC} = C {\sum }_{i = 1}^{total\_gates} \frac{{A}_{{ANT}_{i}}}{{A}_{{OX}_{i}}^{0.7}} \qquad Equation ( 10 )$$

In the embodiments of integrated circuits described herein, the antenna guidelines are always followed, therefore equation (10) can be simplified to the linear form of Equation (10) as follows:

AFR_{IC}=n·AFR₀ Equation (11)

where AFR₀ is the average fail rate of a single transistor from Equation (5) and n is the total number of transistors on the die. As demonstrated by Equation (11), the average fail rate of the integrated circuit is a linear function that is dependent on the number of transistors on the integrated circuit and the reliability, AFR₀, of a single transistor. Based on Equation (11), an integrated circuit with a high number of transistors needs to have a smaller antenna ratio than an integrated circuit with a lower number of transistors. For example, an integrated circuit with one million transistors may have an antenna ratio that is ten times smaller than an integrated circuit with ten million transistors.

In many applications, integrated circuit designers want to connect a large antenna area to a gate in order to allow a large number of interconnections to be made to the gate. Conventional integrated circuit designs had to strictly limit the area of the antennas in order to keep the plasma induced damages to a minimum. In conventional integrated circuits, diodes have to be connected between the antennas and other conductors in order to diffuse the charge build up during the period when the integrated circuits are in the plasma environment when large antennas are used.

The integrated circuits and methods disclosed herein enable larger antennas to be connected to the gates. In one embodiment, an integrated circuit may have approximately one square micron of gate area. Under conventional designs, the antenna area would be limited to one hundred square microns. By using the methods disclosed herein, the antenna area may be increased to one thousand square microns. In addition, no diffusion diodes are required to be connected between the antenna and other conductors to diffuse the charge that is built up in the plasma environment. Therefore, the integrated circuits disclosed herein have less die area and leakage because no diffusion diodes are required to be fabricated into the die.

There are many distinctions between the integrated circuits and methods for fabricating integrated circuits described herein and conventional integrated circuits and fabrication methods. For example, the voltage build up on the gate is a variable function of the antenna ratio and is not required to be maintained constant as it is with conventional integrated circuits. However, the antenna area and not the antenna ratio is used as the metric for determining the failure rate of individual transistors and the integrated circuit as a whole. The antenna area, and thus, the antenna ratio vary depending on the number of gates on the integrated circuit. It follows that the design methods disclosed herein relate to system level design rather than individual transistor design.

Having described integrated circuits and methods of making them, an example of a method for making an integrated circuit based on the foregoing description will now be provided. Reference is made to FIG. 3, which is a flow chart 300 of an embodiment for making an integrated circuit. The process commences at step 304 by selecting a failure rate for the integrated circuit. As described above, the method of making integrated circuits relates the average failure rate of the integrated circuits to the average failure rate of the individual gates multiplied by the number of gates in the integrated circuits. In step 306, the average failure rate of individual gates is calculated as the average failure rate of the integrated circuit divided by the number of gates in the integrated circuit per equation 12.

As described above, the gate area is raised to a power, which is chosen in step 308. In the embodiment described above, the power is one minus the inverse of a chosen slope on the Weibull failure curve for the gate. The power may be related to the voltage that will cause a failure of an individual gate 118. It has been found that a power of 0.7 provides an adequate failure rate for most applications. Accordingly, the gate area is brought to this power. At step 310 the area of the antennas 120 are calculated from equation 10 for an individual transistor 102 based on the gate area and the power to which the gate was raised.

Based on the foregoing, the antenna ratio is a function of the total number of gates 118 on the integrated circuit 100. If an integrated circuit has one million gates, its antenna ratio is ten times less than an integrated circuit having ten million gates and both integrated circuits will have the same fail rate. By fabricating the die 100 using the methods described herein, the antenna areas may be increased depending on the gate area, which may enable greater antenna areas to be connected to the gates. In some situations, the antenna areas may be smaller than those used in conventional integrated circuits, however, the failure rate will remain constant.

The above-described methods can be used for different types of gates fabricated on the same die 100. For example, the die 100 may have gates 118 of a first area and gates 118 of a second area. A constant failure rate for the die 100 is selected. Based on the number of each size of gate, the appropriate antenna areas are calculated. Thus, the failure rate of the die 100 is maintained constant.

While illustrative and presently preferred embodiments of the invention have been described in detail herein, it is to be understood that the inventive concepts may be otherwise variously embodied and employed and that the appended claims are intended to be construed to include such variations except insofar as limited by the prior art.

What is claimed is:

1. A method of fabricating an integrated circuit die, the method comprising:
selecting a failure rate for the die due to the failure of gates fabricated onto the die;
determining the area of the gates;
connecting a conductor to a gate, wherein the area of the conductor is proportional to the area of a gate raised to a power, wherein the power is proportional to the failure rate of an individual gate.

2. The method of claim 1 and further comprising exposing the die to a plasma environment.

3. The method of claim 1 wherein the power is proportional to the inverse of the Weibull slope of a failure model associated with the failure rate of the gate in a plasma environment.

4. The method of claim 1, wherein the power is proportional to the voltage potential across the gate that causes the gate to fail.

5. The method of claim 1, wherein the power is approximately 0.7.

6. The method of claim 1 wherein the method is void of fabricating diffusion diodes between the conductor and a potential, wherein the diffusion diodes would discharge accumulated charge on the conductor when the die is exposed to a plasma environment.
